(19) United States
(12) Patent Application Publication
(10) Pub. No.: US 2026/0116230 A1
(43) Pub. Date: Apr. 30, 2026

(54) CHARGING STATION DOOR

(71) Applicant: SW Solution Co., Ltd., Gimhae-si (KR)

(72) Inventor: Tae Young WOO, Gimhae-si (KR)

(21) Appl. No.: 19/008,601

(22) Filed: Jan. 2, 2025

(30) Foreign Application Priority Data
Jan. 15, 2024 (KR) 10-2024-0006134

(51) Int. Cl. B60L 53/31; F21V 3/00; H05K 5/03; F21Y 115/10

(52) U.S. Cl. CPC B60L 53/31; F21V 3/00; H05K 5/03; F21Y 2115/10

(57) ABSTRACT

Provided is a charging station door, in which a front cover is fixedly coupled to the front of a middle frame, and a rear cover is fixedly coupled to the rear thereof, enhancing assembly efficiency and minimizing the defect rate. The charging station door provided herein is rotatably installed in front of a charging station main body to open or close the front of the charging station main body.

The present application claims priority to Korean Patent Application No. 10-2024-0006134, filed January 15, 2024, the entire contents of which are incorporated herein for all purposes by this reference.

### BACKGROUND OF THE INVENTION

### Field of the Invention

The present disclosure relates to a charging station door, in which a front cover is fixedly coupled to the front of a middle frame, and a rear cover is fixedly coupled to the rear thereof, enhancing assembly efficiency and minimizing the defect rate.

### Description of the Related Art

Recently, with the growing interest in the environment and the advancement in technology, the supply of electric vehicles that do not emit any exhaust gases is increasing, and it is certain that they will replace internal combustion engines that use fossil fuels within a few years. The electric vehicle has a structure in which an electric motor and a battery are built inside the vehicle body, and the electric motor rolls the wheels to drive by the power supplied by the battery, and the driving distance increases depending on the capacity of the battery.

In the electric vehicle, there is a limit to increasing the size or capacity of the battery because the battery is built into a limited space, so the driving distance is shorter than that of conventional internal combustion engine vehicles. As a result, the electric vehicle is frequently charged at charging stations operating inside or outside the building.

The charging station consists of a charging station main body, a charger, a display, and a card reader. The charging station as described above is disclosed in the Korean Patent Publication 10-2019-0135264.

In the conventional charging station, a charging cable or charger is installed on one side of the charging station main body so that it may be extended and connected to the electric vehicle to charge the electric vehicle.

In addition, a charging station door is rotatably installed on the front of the charging station main body so that the interior of the charging station main body may be selectively opened or closed.

These charging station doors are mainly made of metal to increase strength, and in particular, iron plates of different steel or aluminum materials may be bent multiple times and then welded to each other to manufacture charging station doors.

However, in the case of charging station doors, there is a problem in that not only the quality decreases but also the defect rate for the product increases as thermal deformation occurs during the process of welding two or more steel plates.

In addition, as the charging station door is manufactured through the welding method, it not only takes a long time to manufacture, but also has the problem of inconsistent quality depending on the welding skills of the worker.

### Documents of Related Art

(Patent Document 1) Korean Patent Publication 10-2019-0135264

### SUMMARY OF THE INVENTION

Accordingly, the purpose of the present disclosure is to solve the problems of the prior art as described above, and it is to provide a charging station door that may enhance assembly efficiency and minimize the defect rate by fixing a front cover to the front of a middle frame and a rear cover to the rear of the middle frame.

According to the features of the present disclosure to achieve the above purpose, a charging station door according to the present disclosure is rotatably installed in front of a charging station main body to open or close the front of the charging station main body. The charging station door comprises: a middle frame formed of a square frame and installed along the front edge of the charging station main body; a front cover provided at the front of the middle frame and closing the front side of the middle frame; a rear cover provided at the rear of the middle frame and closing the rear side of the middle frame; an LED mounting groove formed recessed along the periphery of the middle frame and in which an LED is installed; and an LED diffusion cover disposed inside the LED mounting groove and diffusing light irradiated from the LED to the outside.

The middle frame includes: a first frame made of a "[" shaped frame and provided at the front side of the charging station; and a second frame made of a "]" shaped frame and installed at the front side of the charging station. A front cover insertion groove is further provided on the inner surfaces of the first frame and the second frame, which is recessed to a predetermined depth and into which the edge of the front cover is fitted. When the first frame and the second frame are assembled, the front cover is fitted and fixed into the front cover insertion groove.

The front cover includes: a front plate made of a rectangular plate, provided on the front side of the middle frame to close the front side of the middle frame; a display mounting hole formed in a square box shape and penetrating forward and backward through the front plate; and a card reader mounting hole formed penetrating forward and backward through the center of the front plate and through which a card reader is installed.

The rear cover includes: a rear plate made of rectangular plates, provided on the rear side of the middle frame to close the rear side of the middle frame; a display mounting part that is recessed by a predetermined depth in the front of the rear plate and in which a display is mounted; a card reader through hole formed through the front and rear of the center of the rear plate and through which a card reader is installed; a plate extension end formed by bending toward the rear along the edge of the rear plate and supporting the rear plate; and a frame fixing end formed by bending toward the middle frame at the end of the plate extension end and tightly coupled to the middle frame.

The inner surfaces of the first and second frames are further provided with a cover fixing end protruding toward the rear cover by a predetermined height and riveted in close contact with the frame fixing end.

The LED diffusion cover includes: an LED diffusion tube that is fitted into the LED mounting groove and protects and diffuses the LED; an LED diffusion part that is recessed in a dome shape on the lower surface of the LED diffusion tube and is arranged above the LED; and a plurality of diffusion grooves that are formed at regular intervals along the inner surface of the LED diffusion part and have a cross-section in the shape of a triangular groove and diffuse the light of the LED.

On both sides of the LED diffusion tube, an airtight maintenance protrusion is further provided with a cross-section formed in a right-angled triangular shape to protrude outward and is in close contact with a wall surface of the middle frame to maintain airtightness.

On both sides of the LED diffusion part, an opaque part is further provided, made of an opaque material, and becomes narrower from the bottom to the top, and guides light passing through the LED diffusion part to the center of the LED diffusion tube.

The charging station door according to the present disclosure has the following effects.

In the present disclosure, the assembly structure of the middle frame, the front cover, and the rear cover is such that the front cover is fitted and fixed to the front of the middle frame, and the rear cover is riveted to the rear of the middle frame. Therefore, the charging station door may be manufactured without a separate welding operation.

This enhances the assembly efficiency of workers compared to charging station doors produced using traditional welding methods. Additionally, as welding-induced thermal deformation is eliminated, the defect rate during assembly and manufacturing is significantly reduced.

In addition, an LED diffusion cover is provided in the LED mounting groove to maintain the LED's airtightness, and the LED dot phenomenon may be removed by the LED diffusion cover, and the light may be uniformly irradiated to the outside of the charging station door.

### BRIEF DESCRIPTION OF THE DRAWINGS

FIG. 1 is a perspective view showing a configuration of a preferred embodiment of a charging station to which the charging station door structure of the present disclosure is applied.

FIG. 2 is a perspective view showing the configuration of the preferred embodiment of the charging station door according to the present disclosure.

FIG. 3 is an exploded perspective view showing the configuration of the preferred embodiment of the charging station door according to the present disclosure.

FIG. 4 is a front view showing the configuration of the preferred embodiment of the charging station door according to the present disclosure.

FIG. 5 is a rear view showing the configuration of the preferred embodiment of the charging station door according to the present disclosure.

FIG. 6 is a rear perspective view showing the configuration of the preferred embodiment of the charging station door according to the present disclosure.

FIG. 7 is a cross-sectional view showing the configuration of the preferred embodiment of the charging station door according to the present disclosure.

FIG. 8 is a front view showing a state in which a front cover is inserted and fixed between a first frame and a second frame according to the present disclosure.

FIG. 9 is an enlarged view showing a state in which the front cover and a rear cover are mounted on a middle frame constituting the embodiment of the present disclosure.

FIG. 10 is an enlarged view showing a state in which an LED and an LED diffusion cover are mounted in an LED mounting groove constituting the embodiment of the present disclosure.

### DETAILED DESCRIPTION OF THE INVENTION

Hereinafter, some embodiments of the present disclosure will be described in detail through exemplary drawings. In adding reference numerals to the components of each drawing, it should be noted that the same components have the same numerals as possible even if they are displayed on different drawings. In addition, in describing an embodiment of the present disclosure, if it is determined that a detailed description of a related known configuration or function hinders understanding of an embodiment of the present disclosure, the detailed description thereof will be omitted.

In addition, terms such as first, second, A, B, (a), and (b) may be used to describe the components of the embodiment of the present disclosure. These terms are only intended to distinguish the component from other components, and the term does not limit the nature, order, or order of the component. When it is stated that a component is "connected", "combined", or "coupled" to another component, it should be understood that another component may be "connected", "combined", or "coupled" between each component, but another component may be "connected", "combined", or "coupled".

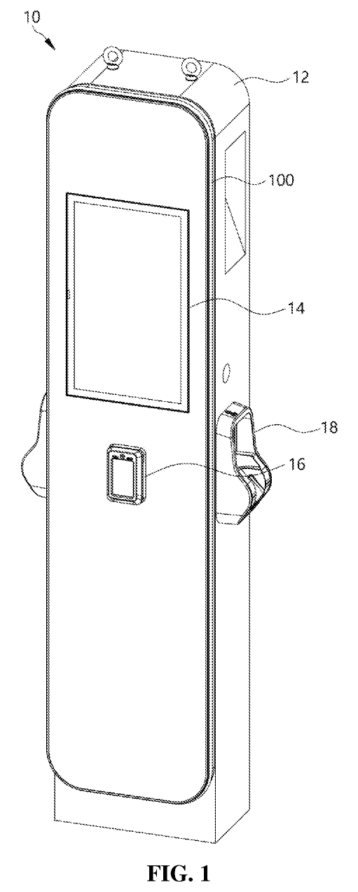

Next, a preferred embodiment of a charging station door of the present disclosure will be described with reference to FIGS. 1 to 10 attached thereto.

The attached FIG. 1 is a perspective view showing the configuration of a preferred embodiment of the charging station to which a charging station door structure of the present disclosure is applied.

First, the charging station in which the charging station door according to the present disclosure is installed will be described. The charging station 10 is largely composed of a charging station main body 12, a display 14, a card reader 16, a charger 18, and the like. The charging station main body 12 is provided with a plurality of components, such as various electronic devices and a control panel therein, and serves to control the supply of power to the charger 18 to be described later.

A display 14 is provided at a front surface of the charging station 10. The display 14 is a general display, and a detailed description thereof will be omitted. The display 14 is provided at a front surface of the charging station main body 12 to display various operation states of the charging station main body 12. For example, the display 14 may display an electric capacity charged in an electric vehicle, a charging amount, an estimated charging time, and a connection state of the charger 18.

Also, a card reader 16 is provided below the display 14. The card reader 16 is a general card reader, and a detailed description thereof will be omitted. The card reader 16 is provided in the charging station main body 12 and is a part for paying a fee when an electric vehicle is charged.

Chargers 18 are provided on both sides of the charging station main body 12. The charger 18 is a general electric vehicle charger, and a detailed description thereof is omitted. The charger 18 may be provided on each of both sides of the charging station main body 12 and may extend from the charging station main body 12 to be connected to the electric vehicle to charge the electric vehicle.

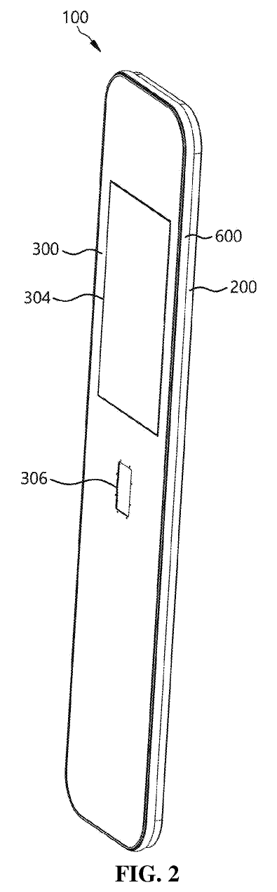

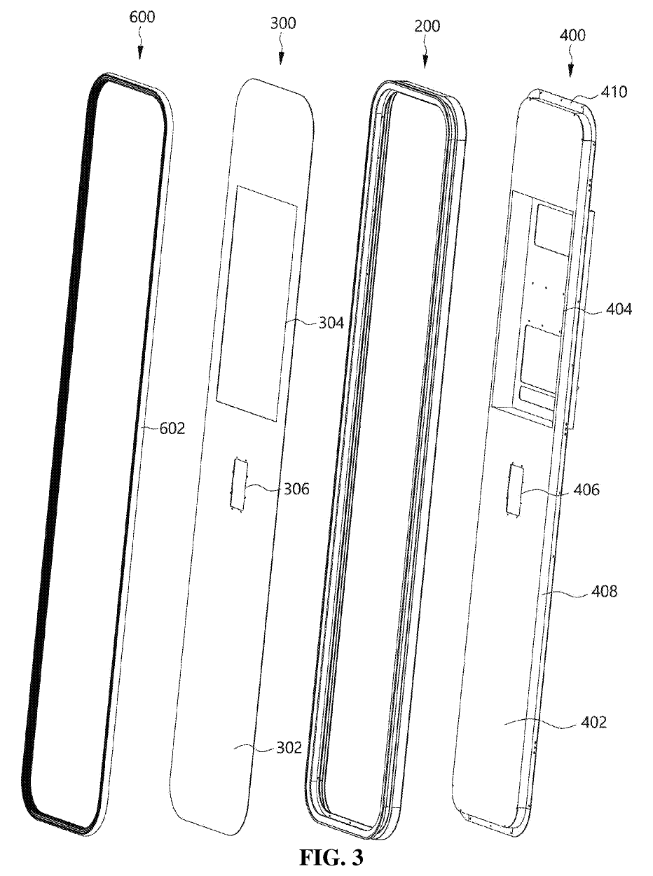

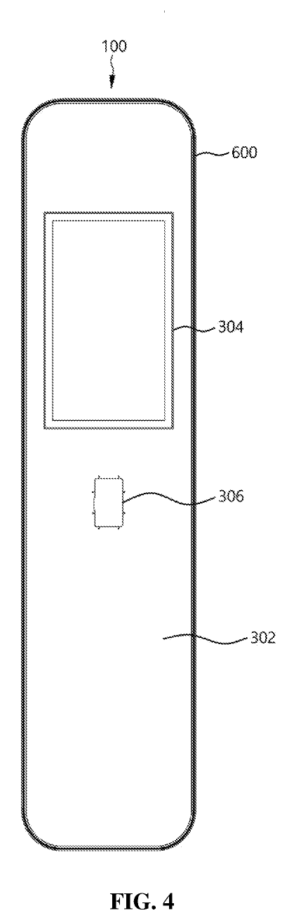

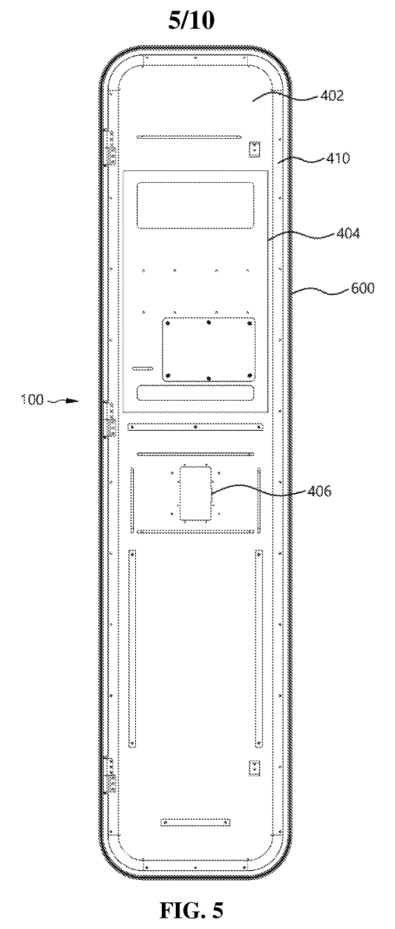

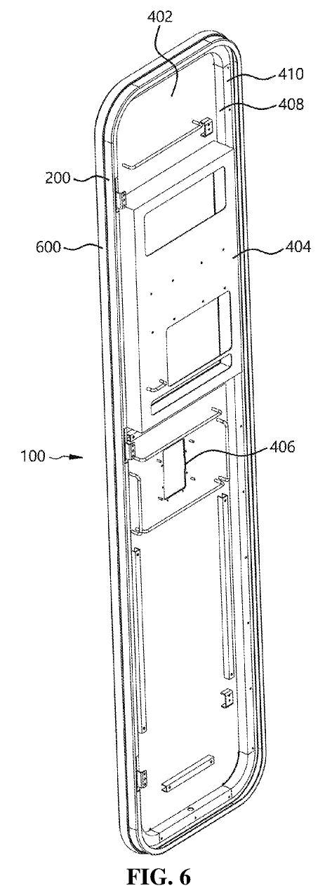

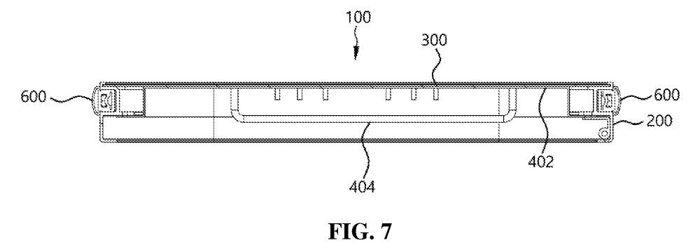

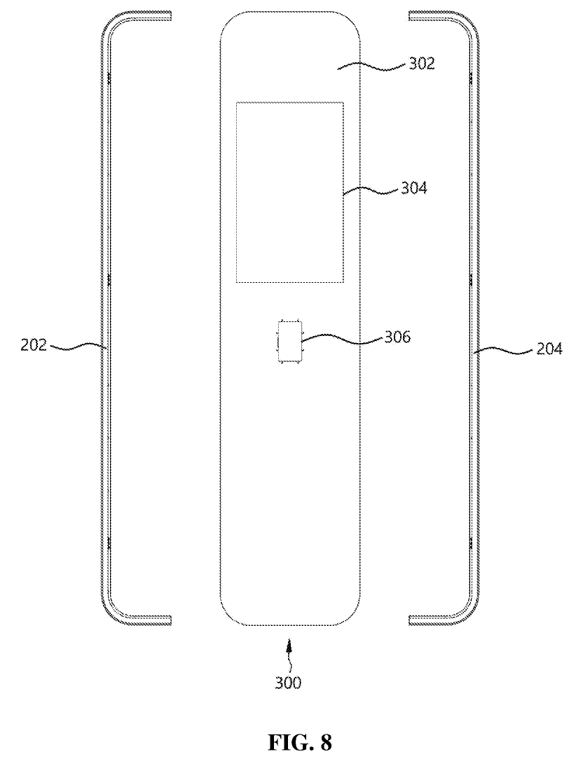

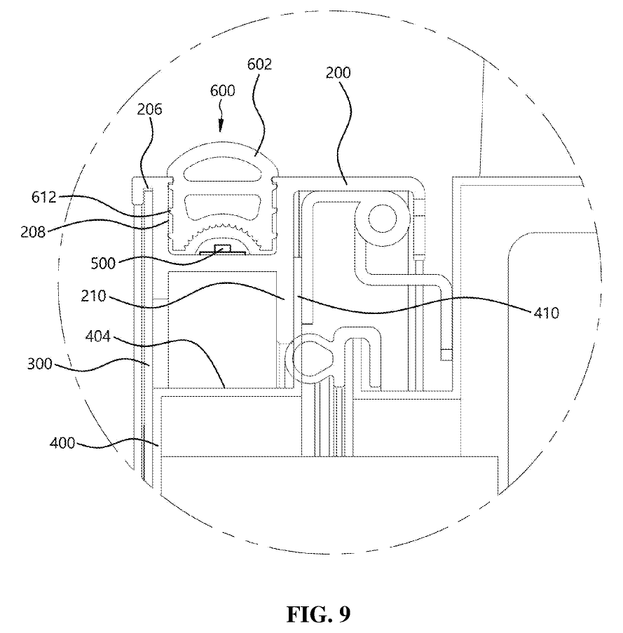

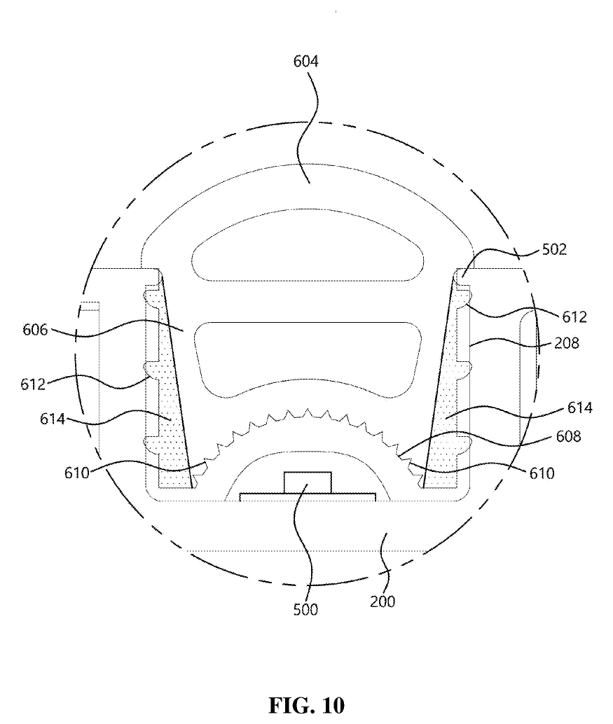

FIG. 2 is a perspective view of the configuration of the preferred embodiment of the charging station door according to the present disclosure, FIG. 3 is an exploded perspective view of the configuration of the preferred embodiment of the charging station door according to the present disclosure, FIG. 4 is a front view of the configuration of the preferred embodiment of the charging station door according to the present disclosure, FIG. 5 is a rear view of the configuration of the preferred embodiment of the charging station door according to the present disclosure, FIG. 6 is a rear perspective view of the configuration of the preferred embodiment of the charging station door according to the present disclosure, FIG. 7 is a cross-sectional view of the configuration of the preferred embodiment of the charging station door according to the present disclosure, FIG. 8 is a front view of a front cover being inserted and fixed between a first frame and a second frame according to the present disclosure, FIG. 9 is an enlarged view of the state in which the front cover and a rear cover are mounted in the middle frame constituting the embodiment of the present disclosure, and FIG. 10 is an enlarged view of the state in which an LED and an LED diffusion cover are mounted in an LED mounting groove constituting the embodiment of the present disclosure.

Next, the preferred embodiment of the charging station door of the present disclosure will be described with reference to FIGS. 2 to 10 attached thereto.

Hereinafter, as shown in these drawings, the charging station door according to the embodiment of the present disclosure is rotatably installed in front of the charging station main body 12 to open or close the front of the charging station main body 12. The charging station door 100 comprises: a middle frame 200 formed of a square frame and installed along the front edge of the charging station 10 ; a front cover 300 provided at the front of the middle frame 200 and closing the front side of the middle frame 200; a rear cover 400 provided at the rear of the middle frame 200 and closing the rear side of the middle frame 200; an LED mounting groove 208 formed recessed along the periphery of the middle frame 200 and in which an LED 500 is installed; and an LED diffusion cover 600 disposed inside the LED mounting groove 208 and diffusing light irradiated from the LED 500 to the outside.

The charging station door 100 is rotatably installed in front of the charging station main body 12 and serves to open or close the front of the charging station main body 12.

The charging station door 100 largely comprises the middle frame 200, the front cover 300, the rear cover 400, and the like.

The middle frame 200 includes a first frame 202 and a second frame 204. The first frame 202 is formed of a frame having a "[" shape, as shown in FIG. 8, and is installed at the front side along a left edge portion of the charging station main body 12. The first frame 202 forms the frame of the charging station door 100 and serves to support the front cover 300 and the rear cover 400 to be described later.

The second frame 204 is installed on the right side of the first frame 202. The second frame 204 is formed of a frame having a "]" shape, and is installed at the front side along a right edge portion of the charging station main body 12. The second frame 204 forms the frame of the charging station door 100, and serves to support the front cover 300 and the rear cover 400, which will be described later, like the first frame 202.

That is, the first frame 202 and the second frame 204 are coupled to each other to form a rectangular frame as shown in FIG. 3. Also, the first frame 202 and the second frame 204 serve to form the entire framework of the charging station door.

A front cover insertion groove 206 is formed in front of the inner surfaces of the first frame 202 and the second frame 204. The front cover insertion groove 206 is recessed by a predetermined depth along inner surfaces of the first frame 202 and the second frame 204, as shown in FIG. 9. An edge portion of the front cover 300 to be described later is inserted into the front cover insertion groove 206 and is a portion to which the front cover 300 to be described later is fixed.

An LED mounting groove 208 is formed at a front side of the circumferential surface of the middle frame 200. The LED mounting groove 208 is recessed in a rectangular box shape along the circumferential surface of the middle frame 200 as shown in FIG. 9. An LED 500 and an LED diffusion cover 600, which will be described later, are installed and fixed inside the LED mounting groove 208.

In addition, a rear cover fixing end 210 is formed on the inner surface of the middle frame 200. The rear cover fixing end 210 is formed to protrude by a predetermined height toward the rear cover 400 to be described later along the inner surface of the middle frame 200 as shown in FIG. 9. The rear cover fixing end 210 is a portion in which a frame fixing end 410 of the rear cover 400, which will be described later, is in close contact with and riveted.

The front cover 300 is provided in front of the middle frame 200. The front cover 300 is largely composed of a front plate 302, a display mounting hole 304, a card reader mounting hole 306, and the like.

The front plate 302 is formed of a rectangular plate having a predetermined thickness and is vertically elongated. The front plate 302 is installed on the front surface with respect to the middle frame 200 and serves to close the front surface of the middle frame 200.

A display mounting hole 304 is formed above the front surface of the front plate 302. The display mounting hole 304 is formed in a rectangular shape and is formed through the front and rear. The display 14 is disposed inside the display mounting hole 304 to be guided to the outside.

A card reader mounting hole 306 is formed at the center of the front surface of the front plate 302. The card reader mounting hole 306 has a shape corresponding to the external appearance of the card reader, and is formed to penetrate forward and backward through the front surface of the front plate 302. The inside of the card reader mounting hole 306 is a portion through which the card reader 16 passes and is guided to the outside.

In the process of assembling the front cover 300 to the middle frame 200, as shown in FIG. 8, the first frame 202 and the second frame 204 are disposed on both sides of the front cover 300, respectively. The front cover 300 may be easily assembled to the middle frame 200 with a simple operation by fitting and fixing the edge portion of the front cover 300 to the front cover insertion groove 206.

The front cover 300 may be firmly assembled to the middle frame 200 by welding the parts where the first frame 202 and the second frame 204 contact each other while the front cover 300 is fitted and fixed to the middle frame 200.

In addition, in order to enhance the attachment strength of the front cover 300 to the middle frame 200, the front cover 300 may be secured more firmly to the middle frame 200 by using additional methods such as welding or riveting.

The rear cover 400 is provided at the rear of the middle frame 200. The rear cover 400 is largely composed of a rear plate 402, a display mounting part 404, a card reader through hole 406, a plate extension end 408, and a frame fixing end 410.

The rear plate 402 is formed of a rectangular plate having a predetermined thickness and is vertically elongated. The rear plate 402 is installed on the rear surface of the middle frame 200 as shown in FIG. 3, and serves to close the rear side of the middle frame 200.

The display mounting part 404 is formed on an upper front surface of the rear plate 402. The display mounting part 404 is formed in a box shape in which the front side thereof is opened, and protrudes toward the rear side of the rear plate 402. The display 14 is disposed and fixed inside the display mounting part 404.

A card reader through hole 406 is formed in a lower portion of the display mounting part 404. The card reader through hole 406 has a shape corresponding to the appearance of the card reader, and is formed to penetrate forward and backward through the front surface of the rear plate 402. The inside of the card reader through hole 406 is a portion through which the card reader 16 passes and is guided to the outside.

A plate extension end 408 is formed at the edge portion of the rear plate 402. The plate extension end 408 is bent rearward along the edge portion of the rear plate 402. The plate extension end 408 is in close contact with the inner surface of the middle frame 200 and serves to support the rear plate 402.

A frame fixing end 410 is formed at the end of the plate extension end 408. The frame fixing end 410 is bent toward the middle frame 200 from the end of the plate extension end 408. The frame fixing end 410 is bent in a direction orthogonal to the plate extension end 408 to closely contact the rear cover fixing end 210 of the middle frame 200.

As shown in FIG. 9, the frame fixing end 410 is closely fixed to the rear cover fixing end 210, and may be firmly fixed to the rear cover fixing end 210 by rivet fixing.

In other words, as the frame fixing end 410 is riveted to the rear cover fixing end 210, the rear cover 400 is firmly fixed to the middle frame 200.

The assembly structure of the middle frame 200, the front cover 300, and the rear cover 400 is such that the front cover 300 is fitted and fixed to the front of the middle frame 200, and the rear cover 400 is riveted to the rear of the middle frame 200. Therefore, the charging station door may be manufactured without a separate welding operation.

Therefore, this enhances the assembly efficiency of workers compared to charging station doors produced using traditional welding methods. Additionally, as welding-induced thermal deformation is eliminated, the defect rate during assembly and manufacturing is significantly reduced.

An LED 500 is disposed on a bottom surface of the LED mounting groove 208 of the middle frame 200. The LED 500 is a general LED module LED, and a detailed description thereof will be omitted. As shown in FIG. 9 or 10, the LED 500 is attached to the front circumferential surface along the bottom surface of the LED mounting groove 208. The LED 500 is disposed in the LED mounting groove 208 and serves to irradiate light to the outside.

A diffusion cover fixing rib 502 is formed on an upper end of the LED mounting groove 208. The diffusion cover fixing rib 502 is formed to protrude by a predetermined height in the inward direction along both sides of the upper end of the LED mounting groove 208. The diffusion cover fixing rib 502 is fitted into and coupled to the LED diffusion cover 600, to be described later, to prevent separation of the LED diffusion cover 600, to be described later.

The LED diffusion cover 600 is disposed inside the LED mounting groove 208. The LED diffusion cover 600 is largely composed of an LED diffusion tube 602, an LED diffusion part 608, a diffusion groove 610, an airtight maintenance protrusion 612, and the like.

The LED diffusion tube 602 includes a diffusion cover 604 having a dome shape in cross section, and a tube body 606 integrally formed under the diffusion cover 604, and having a rectangular cross section.

The diffusion cover 604 has a dome shape and is installed to cover the LED mounting groove 208. The diffusion cover 604 serves to guide light irradiated by the LED 500 so that the light irradiated by the LED 500 may be uniformly irradiated to the outside.

The tube body 606 is integrally formed under the diffusion cover 604. The tube body 606 is formed of a transparent material and is inserted into and fixed to the LED mounting groove 208.

An LED diffusion part 608 is formed on a bottom surface of the tube body 606. The LED diffusion part 608 has a dome shape in cross section and is recessed on the bottom surface of the tube body 606. The LED diffusion part 608 is disposed above the LED 500 and serves to guide the light irradiated from the LED 500 to be radially irradiated.

A diffusion groove 610 is formed on a lower surface of the LED diffusion part 608. The diffusion groove 610 has a triangular groove shape in cross section, and a plurality of diffusion grooves 610 are formed along the lower surface of the LED diffusion part 608 at regular intervals. The plurality of diffusion grooves 610 are disposed on the side of the LED 500 in the irradiation direction of light to diffuse light by irradiating the light of the LED 500 in various directions.

Airtightness maintaining protrusions 612 are formed on both side surfaces of the tube body 606. The airtightness maintaining protrusion 612 has a right-angled triangular shape and protrudes toward the inner wall surface of the LED mounting groove 208. A plurality of airtightness maintaining protrusions 612 are formed at regular intervals from the upper side to the lower side along the side surface of the tube body 606. The airtightness maintaining protrusion 612 is in close contact with the inner wall surface of the LED mounting groove 208 to prevent foreign matters and leakage flowing into the LED 500 and to maintain airtightness.

Opaque parts 614 are formed on both sides of the tube body 606. The opaque parts 614 are made of an opaque material and are formed on both sides of the tube body 606. The opaque parts 614 are disposed on both sides of the LED diffusion part 608, respectively, and are gradually narrowed from the bottom to the top. The opaque parts 614 are disposed on both sides of the LED diffusion part 608 to guide the light irradiated by the LED 500 toward the diffusion cover 604, thereby preventing scattering of light and guiding the light irradiated uniformly.

The LED diffusion cover is provided in the LED mounting groove to maintain the LED's airtightness, and the LED dot phenomenon may be removed by the LED diffusion cover, and the light may be uniformly irradiated to the outside of the charging station door.

The scope of the present disclosure is not limited to the embodiments exemplified above, and within the above technical scope, many other modifications based on the present disclosure may be possible for those skilled in the art.

### Reference Numerals

100. Charging station door

200. middle frame

202. First frame

204. Second frame

206. Front cover insertion groove

208. LED mounting groove

210. Rear cover fixing end

300. Front cover

302. Front plate

304. Display mounting hole

306. Card reader mounting hole

400. Rear cover

402. Rear plate

404. Display mounting part

406. Card reader through hole

408. Plate extension end

410. Frame fixing end

500. LED

502. Diffusion cover fixing rib

600. LED diffusion cover

602. LED diffusion tube

604. Diffusion cover

606. Tube body

608. LED diffusion part

610. Diffusion groove

612. airtight maintenance protrusion

614. Opaque part

1. A charging station door rotatably installed in front of a charging station main body to open or close the front of the charging station main body, comprising:
a middle frame formed of a square frame and installed along the front edge of the charging station main body;
a front cover provided at the front of the middle frame and closing the front side of the middle frame;
a rear cover provided at the rear of the middle frame and closing the rear side of the middle frame;
an LED mounting groove formed recessed along the periphery of the middle frame and in which an LED is installed; and
an LED diffusion cover disposed inside the LED mounting groove and diffusing light irradiated from the LED to the outside.

2. The charging station door of claim 1, wherein middle frame includes:
a first frame made of a "[" shaped frame and provided at the front side of the charging station; and
a second frame made of a "]" shaped frame and provided at the front side of the charging station,
wherein a front cover insertion groove is further provided on the inner surfaces of the first frame and the second frame, which is recessed to a predetermined depth and into which the edge of the front cover is fitted, and
wherein when the first frame and the second frame are assembled, the front cover is fitted and fixed into the front cover insertion groove.

3. The charging station door of claim 1, wherein the front cover includes:
a front plate made of a rectangular plate, provided on the front side of the middle frame to close the front side of the middle frame;
a display mounting hole formed in a square box shape and penetrating forward and backward through the front plate; and
a card reader mounting hole formed penetrating forward and backward through the center of the front plate and through which a card reader is installed.

4. The charging station door of claim 2, wherein the rear cover includes:
a rear plate formed of rectangular plates, provided on the rear side of the middle frame to close the rear side of the middle frame;
a display mounting part that is recessed by a predetermined depth in the front of the rear plate and in which a display is mounted;
a card reader through hole formed through the front and rear of the center of the rear plate and through which a card reader is installed;
a plate extension end formed by bending toward the rear along the edge of the rear plate and supporting the rear plate; and
a frame fixing end formed by bending toward the middle frame at the end of the plate extension end and tightly coupled to the middle frame.

5. The charging station door of claim 4, wherein a rear cover fixing end is further provided protruding toward the rear cover by a predetermined height and riveted in close contact with the frame fixing end in the inner surfaces of the first and second frames.

6. The charging station door of claim 1, wherein the LED diffusion cover includes:
an LED diffusion tube that is fitted into the LED mounting groove and protects and diffuses the LED;
an LED diffusion part that is recessed in a dome shape on the lower surface of the LED diffusion tube and is arranged above the LED; and
a plurality of diffusion grooves that are formed at regular intervals along the inner surface of the LED diffusion part and have a cross-section in the shape of a triangular groove and diffuse the light of the LED.

7. The charging station door of claim 6, wherein an airtight maintenance protrusion is further provided on both sides of the LED diffusion tube, the airtight maintenance protrusion having a cross-section formed in a right-angled triangular shape to protrude outward and being in close contact with a wall surface of the middle frame to maintain airtightness.

8. The charging station door of claim 6, wherein an opaque part is further provided on both sides of the LED diffusion part, the opaque part being made of an opaque material and becoming narrower from the bottom to the top, and guiding light passing through the LED diffusion part to the center of the LED diffusion tube.
